(19) United States
(12) Patent Application Publication
(10) Pub. No.: US 2024/0136262 A1
(43) Pub. Date: Apr. 25, 2024

(54) SEMICONDUCTOR PACKAGE AND METHOD FOR FABRICATING THE SAME

(71) Applicant: Samsung Electronics Co., Ltd., Suwon-si (KR)

(72) Inventor: DONGHYEON JANG, Suwon-si (KR)

(21) Appl. No.: 18/213,850

(22) Filed: Jun. 24, 2023

(30) Foreign Application Priority Data
Oct. 23, 2022 (KR) 10-2022-0137365

(51) Int. Cl. H01L 23/498; H01L 21/48; H01L 23/15

(52) U.S. Cl. CPC H01L 23/49811; H01L 21/4853; H01L 21/4889; H01L 23/15

(57) ABSTRACT

The present disclosure relates to a semiconductor package and a manufacturing method thereof, and a manufacturing method of a semiconductor package according to an embodiment includes: preparing a glass substrate that includes a groove and a hole positioned around the groove; forming a conductive connection member to fill inside the hole of the glass substrate; attaching a semiconductor chip inside the groove of the glass substrate; forming a first redistribution structure for connection with the semiconductor chip and the conductive connection member on a first side of the glass substrate; and forming a second redistribution structure for connection with the conductive connection member on a second side of the glass substrate.

### CROSS-REFERENCE TO RELATED APPLICATION

This application claims priority under 35 U.S.C. § 119 to and the benefit of Korean Patent Application No. 10-2022-0137365, filed in the Korean Intellectual Property Office on Oct. 24, 2022, the entire contents of which are incorporated herein by reference.

### BACKGROUND

### 1. Field

The present disclosure relates to a semiconductor package and a manufacturing method thereof.

### 2. Description of the Related Art

A semiconductor is a material that belongs to an intermediate class between a conductor and an insulator, and refers to a material that conducts electricity under predetermined conditions. Various semiconductor elements can be manufactured using the semiconductor material, and for example, memory devices and the like can be manufactured. Such a semiconductor element can be used in various electronic devices.

Semiconductor chips can be affected by various external environments such as temperature, humidity, and impact. A packaging process can be performed to protect the semiconductor chip from these external environments and to electrically connect a product such that it can operate. Such a packaging process may include wafer cutting, chip bonding, metal connection, a molding process, and the like.

Recently, as high-capacity, high-performance semiconductors are required, technologies for making semiconductor packages thinner and smaller are being developed. In addition, it is necessary to develop technology to simplify the process and improve stability and reliability.

### SUMMARY

Embodiments are to provide a semiconductor package that can improve stability and reliability, and a manufacturing method thereof.

A manufacturing method of a semiconductor package according to an embodiment includes: preparing a glass substrate that includes a groove and a hole positioned at a side of the groove; forming a conductive connection member to fill inside the hole of the glass substrate; attaching a semiconductor chip inside the groove of the glass substrate; forming a first redistribution structure for connection with the semiconductor chip and the conductive connection member on a first side of the glass substrate; and forming a second redistribution structure for connection with the conductive connection member on a second side of the glass substrate.

A plurality of holes may be positioned on both sides of the groove, respectively, a depth of each of the plurality of holes may be about 300 μm or more and about 500 μm or less, and a width of each of the plurality of holes may be about 20 μm or more and about 200 μm or less.

A thickness of a portion of the glass substrate positioned below the groove may be about 50 μm or more and about 100 μm or less.

An angle of inclination between a bottom surface and a side surface of the glass substrate inside the groove may be about 90 degrees or more and about 95 degrees or less.

In the forming of the conductive connection member, the conductive connection member may be formed by filling a conductive material in the form of paste inside the hole.

In the forming of the conductive connection member, a first side of the conductive connection member may be coplanar with a first side of the glass substrate, and a second side of the conductive connection member may be coplanar with a second side of the glass substrate.

The semiconductor chip may be attached to a bottom surface of the glass substrate inside the groove, and an adhesive member may be positioned between the semiconductor chip and the glass substrate.

The semiconductor chip may include an electrode, and the first redistribution structure may be connected to the electrode of the semiconductor chip.

The first redistribution structure may include: at least one wiring layer connected to the conductive connection member and the semiconductor chip; a pad portion connected to the at least one wiring layer; and an insulation layer positioned between the at least one wiring layer and the glass substrate, between wiring layers of the at least one wiring layer, and between the at least one wiring layer and the pad portion.

The second redistribution structure may include: at least one wiring layer connected to the conductive connection member; and an insulation layer positioned between the at least one wiring layer and the glass substrate and between wiring layers of the at least one wiring layer.

The manufacturing method of the semiconductor package according to the embodiment may further include forming a connection member connected with the pad portion on the first redistribution structure.

The glass substrate may include a plurality of grooves, and a plurality of holes positioned around the respective grooves, and a semiconductor chip may be attached to the inside of each of the plurality of grooves.

The manufacturing method of the semiconductor package according to the embodiment may further include separating the glass substrate into a plurality of semiconductor packages through a cutting process.

The manufacturing method of the semiconductor package according to the embodiment may further include: attaching a carrier substrate to the glass substrate; and separating the carrier substrate from the glass substrate after forming the first redistribution structure, wherein the second redistribution structure may be formed after separating the carrier substrate from the glass substrate.

A manufacturing method of a semiconductor package according to an embodiment includes: preparing a glass substrate that includes a groove and a hole positioned at a side of the groove; attaching a carrier substrate to the glass substrate; forming a conductive connection member to fill the inside of the hole of the glass substrate using an electroplating process; attaching a semiconductor chip to the inside of the groove of the glass substrate; forming a first redistribution structure for connection with the semiconductor chip and the conductive connection member on a first side of the glass substrate; separating the carrier substrate from the glass substrate; and forming a second redistribution structure for connected with the conductive connection member on a second side of the glass substrate.

The manufacturing method of the semiconductor package according to the embodiment may further include forming a photoresist pattern on the first side of the glass substrate, wherein the first redistribution structure may be formed in a portion where the photoresist pattern is not formed using an electroplating process.

The forming the conductive connection member and the forming at least a part of the first redistribution structure may be carried out in a single process, and the semiconductor chip may be attached after forming the at least the part of the first redistribution structure.

The first redistribution structure may be formed to extend to the inside of the groove, and the semiconductor chip may be positioned on the first redistribution structure inside the groove.

The glass substrate may further include an auxiliary hole positioned below the groove, and the semiconductor chip and the first redistribution structure may be connected through the auxiliary hole.

A semiconductor package according to an embodiment includes: a glass substrate that includes a groove and a plurality of holes positioned around the groove; a semiconductor chip positioned inside the groove of the glass substrate and attached to the glass substrate; a plurality of conductive connection members positioned inside the plurality of holes of the glass substrate; a first redistribution structure positioned on a first side of the glass substrate and connected to the semiconductor chip and the plurality of conductive connection members; a connection member positioned on the first redistribution structure; and a second redistribution structure positioned on a second side of the glass substrate and connected to the plurality of conductive connection members.

According to the embodiments, stability and reliability of a semiconductor package can be improved.

### BRIEF DESCRIPTION OF THE DRAWINGS

FIG. 1A to FIG. 1I sequentially illustrate a manufacturing method of a semiconductor package, according to an example embodiment.

FIG. 2A to FIG. 2I sequentially show a manufacturing method of a semiconductor package, according to an example embodiment.

FIG. 3A to FIG. 3I sequentially show a semiconductor package and a manufacturing method thereof, according to an example embodiment.

FIG. 4A to FIG. 4I sequentially show a semiconductor package and a manufacturing method thereof, according to an example embodiment.

### DETAILED DESCRIPTION

Hereinafter, various embodiments will be described in detail with reference to the accompanying drawings, and thus a person of an ordinary skill can easily perform it in the technical field to which the present invention belongs. The present invention may be implemented in several different forms and is not limited to the embodiments described herein.

In order to clearly explain the present invention, parts irrelevant to the description are omitted, and the same reference numerals refer to the same or similar constituent elements throughout the specification.

In addition, since the size and thickness of each component shown in the drawing are arbitrarily indicated for better understanding and ease of description, the present invention is not necessarily limited to the drawings. In the drawings, the thickness of layers, films, panels, regions, etc., are exaggerated for clarity. In addition, in the drawing, the thickness of some layers and regions is exaggerated for better understanding and ease of description.

It will be understood that when an element such as a layer, film, region, or substrate is referred to as being “on” another element, it can be directly on the other element or intervening elements may also be present. In contrast, when an element is referred to as being “directly on” another element, or as “contacting” or “in contact with” another element (or using any form of the word “contact”), there are no intervening elements present at the point of contact. Further, throughout the specification, the word “on” a target element will be understood to mean positioned above or below the target element, and will not necessarily be understood to mean positioned “at an upper side” based on an opposite to gravity direction.

Terms such as “same,” “equal,” “planar,” or “coplanar,” as used herein when referring to orientation, layout, location, shapes, sizes, amounts, or other measures do not necessarily mean an exactly identical orientation, layout, location, shape, size, amount, or other measure, but are intended to encompass nearly identical orientation, layout, location, shapes, sizes, amounts, or other measures within acceptable variations that may occur, for example, due to manufacturing processes. The term “substantially” may be used herein to emphasize this meaning, unless the context or other statements indicate otherwise. For example, items described as “substantially the same,” “substantially equal,” or “substantially planar,” may be exactly the same, equal, or planar, or may be the same, equal, or planar within acceptable variations that may occur, for example, due to manufacturing processes.

In addition, unless explicitly described to the contrary, the word “comprise”, and variations such as “comprises” or “comprising”, will be understood to imply the inclusion of stated elements but not the exclusion of any other elements.

Further, throughout the specification, the phrase “on a plane” means viewing a target portion from the top, and the phrase “on a cross-section” means viewing a cross-section formed by vertically cutting a target portion from the side.

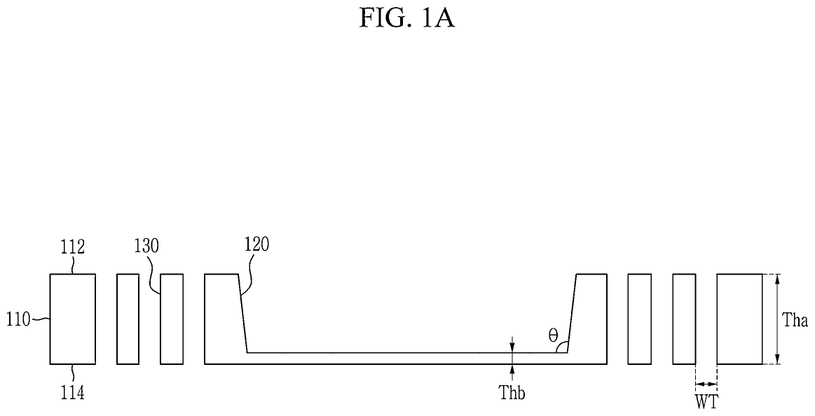

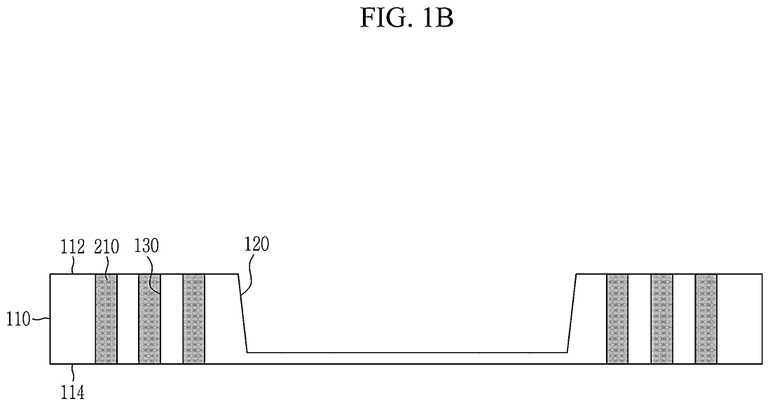

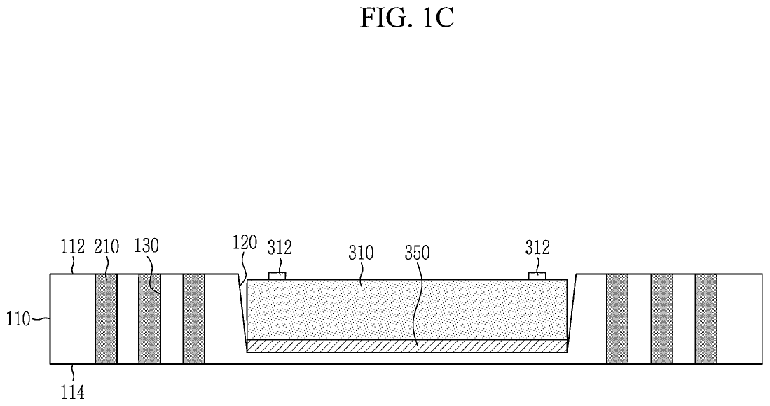

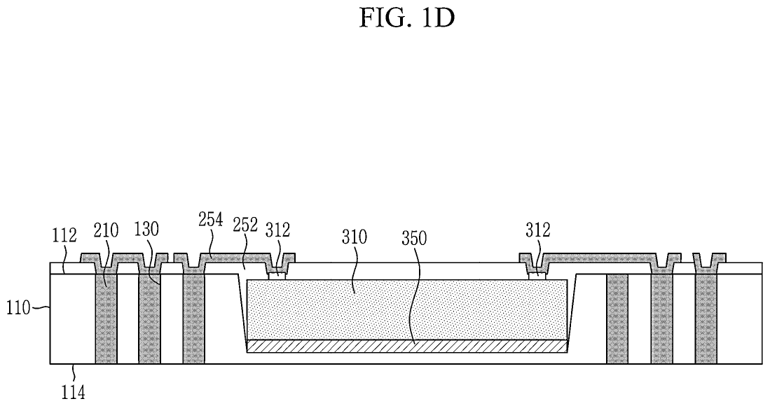

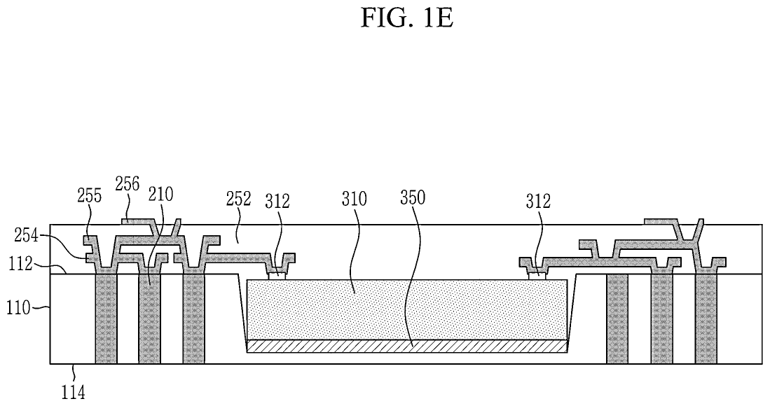

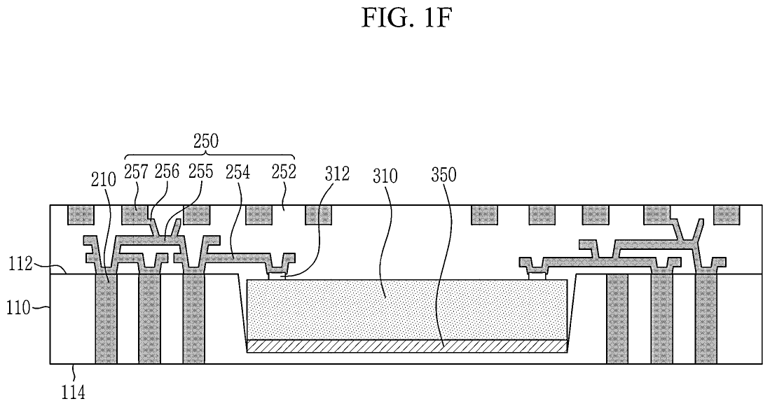

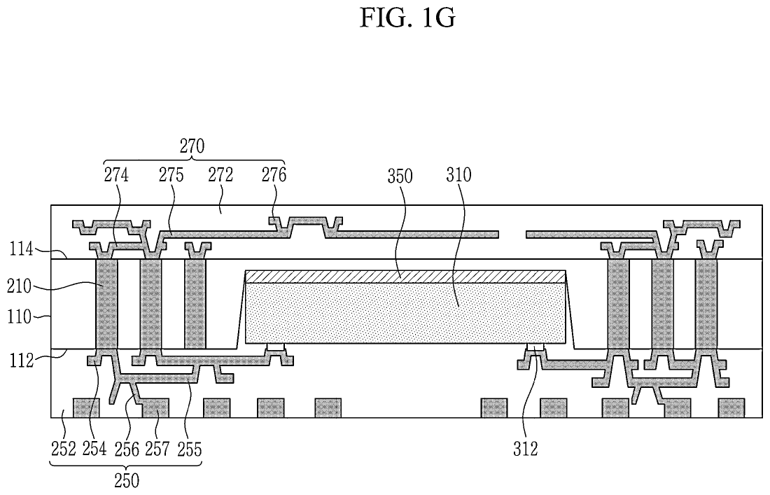

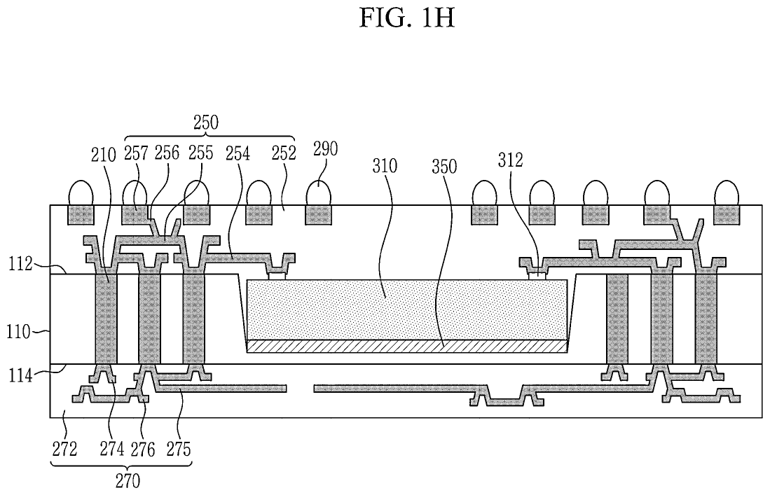

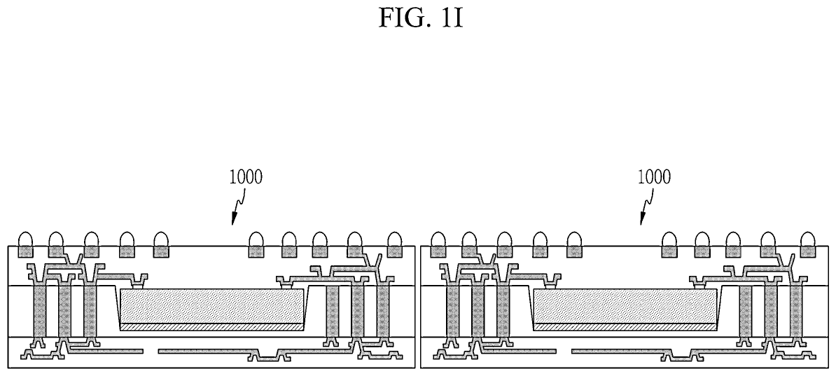

Hereinafter, a semiconductor package according to an embodiment and a manufacturing method thereof will be described with reference to FIG. 1A to FIG. 1I.

FIG. 1A to FIG. 1I sequentially illustrate a manufacturing method of a semiconductor package, according to an example embodiment.

As shown in FIG. 1A, a glass substrate 110 is prepared.

The glass substrate 110 may be made of a hard glass material. The glass substrate 110 may include a first side 112 and a second side 114 that face each other. For example, the first side 112 of the glass substrate 110 may be a top surface, and the second side 114 of the glass substrate 110 may be a bottom surface. However, the glass substrate 110 may be turned over during the process, and the top and bottom surfaces can be changed.

The glass substrate 110 includes a groove 120 and holes 130. The groove 120 refers to a part that is depressed by a predetermined depth from the first side 112 of the glass substrate 110. The holes 130 means empty portions passing through the glass substrate 110. The groove 120 may be positioned approximately at a center of the glass substrate 110, and the holes 130 may be positioned on both sides of the groove 120. On the cross-section, the holes 130 are shown to be positioned on the left and right sides of the groove 120, and on a plan view, the holes 130 may be disposed at a predetermined interval to surround the groove 120. It is shown that three holes 130 are positioned at regular intervals on the left side of the groove 120, and three holes 130 are positioned at regular intervals on the right side of the groove 120, but it is not limited thereto. The number of holes 130 and the alignment form can be variously changed.

An inclination angle θ formed by the bottom surface and the side surface of the glass substrate 110 in the groove 120 may be about 90 degrees to about 95 degrees. However, this is not restrictive, and the range of the inclination angle θ may be variously changed. A thickness Tha of the glass substrate 110 may be about 300 μm or more and about 500 μm or less. A depth of the hole 130 may correspond to the thickness Tha of the glass substrate 110. Accordingly, the depth of the holes 130 may be greater than or equal to about 300 μm and less than or equal to about 500 μm. A width WT of the hole 130 may be about 20 μm or more and about 200 μm or less. When a planar shape of the hole 130 is circular, the width WT of the hole 130 may mean a diameter. In a portion where the groove 120 is formed, the thickness of the glass substrate 110 may be formed to be relatively thin. A thickness Thb of the portion of the glass substrate 110 positioned below the groove 120 may be about 50 μm or more and about 100 μm or less. However, the range of values such as the inclination angle θ inside the groove 120 described above, the thickness Tha of the glass substrate 110, the width WT of the hole 130, and the thickness Thb of the portion of the glass substrate 110 positioned below the groove 120 are not limited thereto and may be variously changed.

As shown in FIG. 1B, conductive connection members 210 are formed in the holes 130 of the glass substrate 110.

The conductive connection member 210 may be formed to fill the insides of the holes 130. Accordingly, a width of the conductive connection member 210 may correspond to the width WT of the hole 130. Similarly, a thickness of the conductive connection member 210 may correspond to the depth of the hole 130. The conductive connection member 210 may include a conductive material. For example, the conductive connection member 210 may include copper (Cu), nickel (Ni), aluminum (Al), gold (Au), silver (Ag), or a combination thereof. The conductive connection member 210 may be formed by filling the inside of the hole 130 with a conductive material in the form of a paste. An upper surface of the conductive connection member 210 may be planarized with the first side 112 of the glass substrate 110. The bottom surface of the conductive connection member 210 may be planarized with the second side 114 of the glass substrate 110. However, it is not limited thereto, and the conductive connection member 210 may be more protruded than the first side 112 or second side 114 of the glass substrate 110. For example, the conductive connection member 210 may protrude above the first side 112 and/or below the second side 114 of the glass substrate 110.

As shown in FIG. 10, a semiconductor chip 310 may be attached to the inside of the groove 120 of the glass substrate 110.

For example, the semiconductor chip 310 may be a logic semiconductor chip or a memory semiconductor chip. The logic semiconductor chip may include a central processing unit (CPU), a controller, an application processor, or an application specific integrated circuit (ASIC). The memory semiconductor chip may include a DRAM (dynamic random access memory), an SRAM (static random access memory), a flash memory, an EEPROM (electrically erasable programmable read-only memory), a PRAM (phase change random access memory), an MRAM (magnetic random access memory), or a RRAM (resistive random access memory).

The semiconductor chip 310 may be attached to the inner bottom surface of the groove 120 of the glass substrate 110 using an adhesive member 350. The adhesive member 350 is positioned between the glass substrate 110 and the semiconductor chip 310 within the groove 120. The adhesive member 350 may be formed in a film form or a paste form. The adhesive member 350 may include a nonconductive adhesive, an anisotropic conductive adhesive, or an isotropic conductive adhesive. The nonconductive adhesives may include polymeric resins. The anisotropic conductive adhesive and the isotropic conductive adhesive may contain a polymer resin and conductive particles. For example, the polymer resin may include a thermosetting resin, a thermoplastic resin, a UV curable resin, and the like, and the conductive particle may include nickel (Ni), gold (Au), silver (Ag), copper (Cu), and the like. However, it is not limited thereto, and the material and shape of the adhesive member 350 may be variously changed.

The size of the semiconductor chip 310 may correspond to the size of the groove 120 of the glass substrate 110. The size of the groove 120 of the glass substrate 110 may be greater than or substantially equal to the size of the semiconductor chip 310. The groove 120 of the glass substrate 110 may have a sufficient size to accommodate the semiconductor chip 310. The width of the groove 120 may be similar to that of the semiconductor chip 310. For example, the width at the bottom of the groove 120 may be substantially the same as or greater than a width of the semiconductor chip 310. The depth of the groove 120 may be similar to the sum of the thickness of the semiconductor chip 310 and the thickness of the adhesive member 350. For example, a depth of the groove 120 may be substantially the same as or greater than the sum of the thicknesses of the semiconductor chip 310 and the adhesive member 350.

The semiconductor chip 310 may include an electrode 312. The electrode 312 may be positioned on the upper surface of the semiconductor chip 310 and may be made of a conductive material. The semiconductor chip 310 may be electrically connected to another member through the electrode 312. In example embodiments, the semiconductor chip 310 may include a plurality of electrodes 312, and the semiconductor chip 310 may be electrically connected to another member through the plurality of electrodes 312. An electrode may not be formed on the bottom surface of the semiconductor chip 310 that is in contact with the adhesive member 350.

As shown in FIG. 1D, an insulation layer 252 and a first wiring layer 254 are formed on the first side 112 of the glass substrate 110.

First, an insulation layer 252 is formed on the first side 112 of the glass substrate 110 using an insulating material. The insulation layer 252 may be formed using an organic insulating material such as polyimide (PI), polybenzoxazole (PBO), or benzocyclobutene (BCB), or an inorganic insulating material such as a silicon oxide, a silicon nitride, or a silicon oxynitride.

A space may exist between the groove 120 of the glass substrate 110 and the semiconductor chip 310. For example, the groove 120 of the glass substrate 110 may be larger than the semiconductor chip 310, and a sidewall of the groove 120 may be spaced apart from the semiconductor chip 310. A space between the sidewall of the groove 120 and the semiconductor chip 310 may be filled by the insulation layer 252. For example, the insulating layer 252 may contact the first side 112, a side surface of the groove 120, and top and side surfaces of the semiconductor chip 310.

Via holes are formed by patterning the insulation layer 252, and the first wiring layer 254 may be connected to the conductive connection members 210 and the electrodes 312 of the semiconductor chip 310 through the via holes. The first wiring layer 254 may be formed on the insulation layer 252 and may be formed inside the via holes. The first wiring layer 254 may contact the conductive connection members 210 and may be electrically connected thereto. The first wiring layer 254 may contact the electrodes 312 of the semiconductor chip 310 and may be electrically connected thereto. The semiconductor chip 310 may be connected to the first wiring layer 254 through the electrodes 312. The semiconductor chip 310 and the conductive connection members 210 may be connected to each other through the first wiring layer 254.

As shown in FIG. 1E, an insulation layer 252, a second wiring layer 255, and a third wiring layer 256 are formed on the first wiring layer 254.

The insulation layer 252 formed previously and the insulation layer 252 formed in this step may be made of the same material, and may be formed integrally such that they are marked as one reference numeral, but are not limited thereto. In some cases, an insulation layer 252 positioned between the conductive connection member 210 and the first wiring layer 254, an insulation layer 252 positioned between the first wiring layer 254 and the second wiring layer 255, and an insulation layer 252 positioned between a second wiring layer 255 and a third wiring layer 256 may be formed of different materials, and the layers may be separated from each other.

The second wiring layer 255 may be positioned on the first wiring layer 254. The second wiring layer 255 may be connected to the first wiring layer 254 through via holes formed in the insulation layer 252. The third wiring layer 256 may be positioned on the second wiring layer 255. The third wiring layer 256 may be connected to the second wiring layer 255 through via holes formed in the insulation layer 252.

As shown in FIG. 1F, pads portion 257 are formed on the third wiring layer 256. The pad portions 257 may contact the third wiring layer 256 and may be electrically connected to the third wiring layer 256.

The insulation layer 252 formed on the first side 112 of the glass substrate 110, the first wiring layer 254, the second wiring layer 255, the third wiring layer 256, and the pad portions 257 may form a first redistribution structure 250. Accordingly, a first redistribution structure 250 connected to the semiconductor chip 310 and the conductive connection members 210 may be formed on the first side 112 of the glass substrate 110.

The first wiring layer 254, the second wiring layer 255, the third wiring layer 256, and the pad portion 257 include copper (Cu), nickel (Ni), gold (Au), silver (Ag), aluminum (Al), tungsten (W), titanium (Ti), tantalum (Ta), titanium nitride (TiN), tantalum nitride (TaN), or a combination thereof.

In the above, the first redistribution structure 250 has been described as including three wiring layers, but is not limited thereto. For example, the first redistribution structure 250 may include two or fewer wiring layers or may include four or more wiring layers.

As shown in FIG. 1G, the glass substrate 110 is turned over such that the second side 114 is placed on top. Subsequently, a second redistribution structure 270 is formed on the second side 114 of the glass substrate 110.

When the glass substrate 110 is turned over, the second side 114 is placed on the top and the first side 112 is placed on the bottom. With the second side 114 of the glass substrate 110 facing up, the process of forming the second redistribution structure 270 may proceed.

The second redistribution structure 270 may include an insulation layer 272, a first wiring layer 274, a second wiring layer 275, and a third wiring layer 276. The second redistribution structure 270 may be formed using a process similar to the process of forming the first redistribution structure 250.

The insulation layer 272 may be formed using an organic insulating material such as polyimide (PI), polybenzoxazole (PBO), or benzocyclobutene (BCB), or an inorganic insulating material such as a silicon oxide, a silicon nitride, or a silicon oxynitride. The first wiring layer 274, the second wiring layer 275, and the third wiring layer 276 may include copper (Cu), nickel (Ni), gold (Au), silver (Ag), aluminum (Al), tungsten (W), titanium (Ti), tantalum (Ta), titanium nitride (TiN), tantalum nitride (TaN), or a combination thereof.

The first wiring layer 274 of the second redistribution structure 270 may be connected to the conductive connection members 210. An insulation layer 272 may be positioned between the first wiring layer 274 and the conductive connection members 210. The second wiring layer 275 may be connected to the first wiring layer 274. An insulation layer 272 may be positioned between the first wiring layer 274 and the second wiring layer 275. The third wiring layer 276 may be connected to the second wiring layer 275. The insulation layer 272 may be positioned between the second wiring layer 275 and the third wiring layer 276.

The second redistribution structure 270 has been described above as including three wiring layers, but is not limited thereto. For example, the second redistribution structure 270 may include two or fewer wiring layers or may include four or more wiring layers.

As shown in FIG. 1H, the glass substrate 110 is turned over again such that the first side 112 is placed on top. Next, connection members 290 are formed on the first redistribution structure 250.

When the glass substrate 110 is turned over, the first redistribution structure 250 is placed on top and the second redistribution structure 270 is placed on the bottom. With the first redistribution structure 250 on top, the process of forming the connection members 290 can proceed. The connection members 290 may be connected to the pad portions 257 of the first redistribution structure 250. For example, each of the connection members 290 may be connected to a corresponding one of the pad portions 257.

The connection members 290 may include a conductive bump, a solder ball, a conductive spacer, a pin grid array (PGA), and a combination thereof. For example, the conductive bump may include a conductive material such as copper (Cu), aluminum (Al), or gold (Au), and the solder ball may include tin (Sn)/lead (Pb) or tin (Sn)/silver (Ag)/copper (Cu).

Although not shown, an under bump metal pattern may be further positioned between the connection member 290 and the pad portion 257 of the first redistribution structure 250. For example, the under bump metal pattern is a metal such as chromium (Cr), tungsten (W), titanium (Ti), copper (Cu), nickel (Ni), aluminum (Al), palladium (Pd), gold (Au), and the like.

As shown in FIG. 1I, a plurality of semiconductor packages 1000 may be separated by a dicing process.

In FIG. 1A to FIG. 1H, one groove 120 included in the glass substrate 110 and one semiconductor chip 310 positioned within the groove 120 are illustrated. The glass substrate 110 may include at least one groove 120 and a plurality of holes 130 positioned around each groove 120, and the semiconductor chip 310 may be positioned within each groove 120. In FIG. 1A to FIG. 1H, only one of the plurality of grooves 120 and only one of the plurality of semiconductor chips 310 may be illustrated. Each of the plurality of grooves 120 may have the same shape as the groove 120 shown in in FIG. 1A to FIG. 1H. For example, the plurality of grooves 120 may be repeatedly disposed on the glass substrate 110, and one semiconductor chip 310 may be positioned within each groove 120. However, it is not limited thereto, and the plurality of semiconductor chips 310 may be positioned within each groove 120.

Accordingly, the plurality of semiconductor packages 1000 may be formed using one glass substrate 110. A plurality of semiconductor packages 1000 may be separated by performing a process of cutting the glass substrate 110. Although FIG. 1I shows two semiconductor packages 1000, this shows how the semiconductor packages 1000 are separated from each other, and actually two or more semiconductor packages 1000 can be completed.

The semiconductor package 1000 according to the embodiment may be manufactured by the semiconductor package manufacturing method shown in FIG. 1A to FIG. 1I. The semiconductor package 1000 according to the embodiment may include a glass substrate 110 including a groove 120 and holes 130, conductive connection members 210 positioned inside the holes 130 of the glass substrate 110, a semiconductor chip 310 positioned inside the groove 120 of the glass substrate 110, a first redistribution structure 250 positioned on the first side 112 of the glass substrate 110, and a second redistribution structure 270 positioned on the second side 114 of the glass substrate 110.

The holes 130 may be positioned at opposite sides of the groove 120 of the glass substrate 110. Thus, the conductive connection members 210 may be positioned at opposite sides of the semiconductor chip 310.

The conductive connection members 210 may be formed to fill inside the holes 130, and the semiconductor chip 310 may be attached to the glass substrate 110 in the groove 120. An adhesive member 350 may be positioned between the semiconductor chip 310 and the glass substrate 110 in the groove 120. For example, the semiconductor chip 310 may be fixed to the glass substrate 110 by the adhesive member 350.

The semiconductor chip 310 may include electrodes 312, and the electrodes 312 of the semiconductor chip 310 may be connected with the first redistribution structure 250.

The first side 112 and the second side 114 of the glass substrate 110 may face each other. The first redistribution structure 250 and the second redistribution structure 270 may be formed at opposite sides of the glass substrate 110. The first redistribution structure 250 may include an insulation layer 252, at least one of wiring layers 254, 255, and 256, and pad portions 257. The pad portions 257 of the first redistribution structure 250 may be connected to the electrodes 312 of the semiconductor chip 310. The second redistribution structure 270 may include an insulation layer 272, an d at least one of wiring layers 274, 275, and 276.

The semiconductor package 1000 according to the embodiment may further include connection members 290. The connection members 290 may be connected to the pad portions 257 of the first redistribution structure 250.

Hereinafter, a semiconductor package according to a comparative example will be described in comparison with the semiconductor package according to the embodiment.

In a semiconductor package according to a comparative example, a first redistribution structure is formed on a carrier substrate, a conductive connection member and a semiconductor chip are formed on the first redistribution structure, and a sealing member is formed to cover the first redistribution structure and the semiconductor chip. A second redistribution structure is formed on the sealing member, and the carrier substrate is separated. A connection member connected to the first redistribution structure is formed, and a dicing process is performed.

In the semiconductor package according to the comparative example, the sealing member may be formed of an organic material such as an epoxy molding compound (EMC). The semiconductor chip may be covered by the sealing member, and a lifting phenomenon may occur between the semiconductor chip and the sealing member. This is due to heterogeneity between the material of the semiconductor chip and the material of the sealing member. In addition, a problem of contamination of the semiconductor chip by the sealing member may occur in the manufacturing process.

In the semiconductor package according to an embodiment, the semiconductor chip is adjacent to the glass substrate, and since the semiconductor chip and the glass substrate contain a silicon material, they can have structural stability due to the homogeneity of the materials. For example, the semiconductor chip and the glass substrate may have similar coefficients of thermal expansion (CTE). In addition, it is possible to prevent semiconductor chips from being contaminated in the manufacturing process, thereby improving reliability.

In addition, in the process of manufacturing the semiconductor package according to the comparative example, a carrier substrate is used and thus the process may be complicated and the cost may increase. The process can be simplified and costs can be reduced by omitting the use of such a carrier substrate in the process of manufacturing a semiconductor package according to an embodiment.

The glass substrate used in the semiconductor package manufacturing method according to the embodiment may be formed thick enough to allow the process to proceed without the use of a separate carrier substrate. Therefore, in the present embodiment, the depth of the groove of the glass substrate can be formed to be relatively thick, and even though the thickness of the semiconductor chip is thick, it can be sufficiently mounted in the groove. Accordingly, the thickness of the completed semiconductor package may be thick. The present embodiment may be suitable for manufacturing a thick semiconductor package.

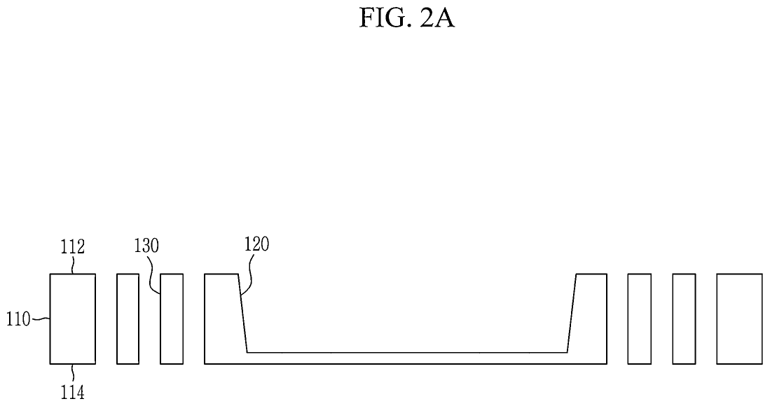

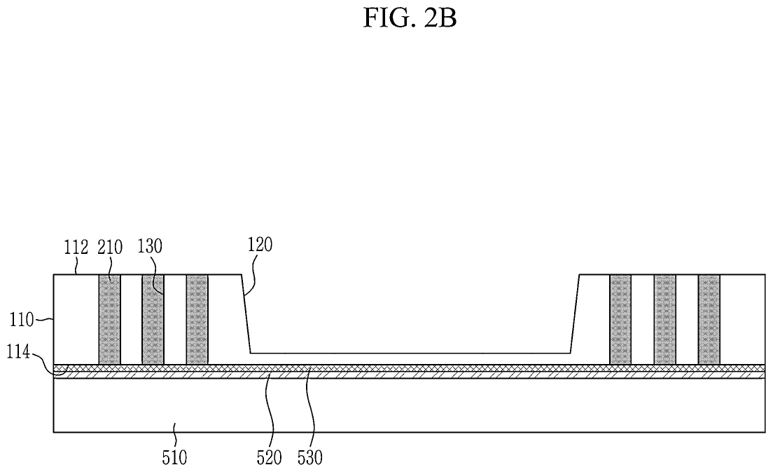

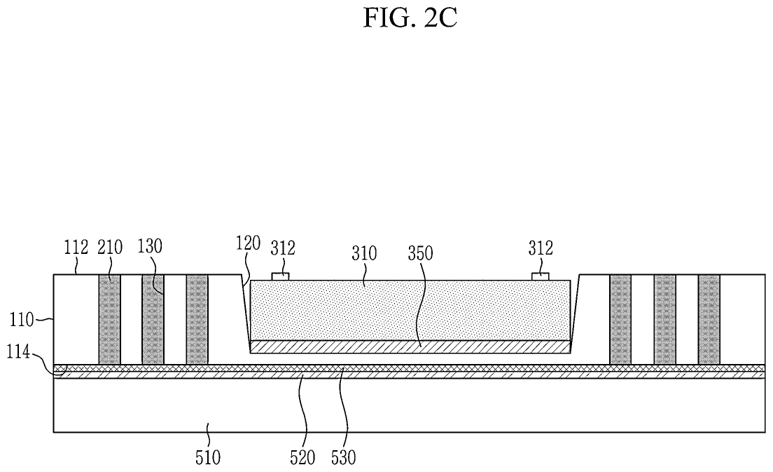

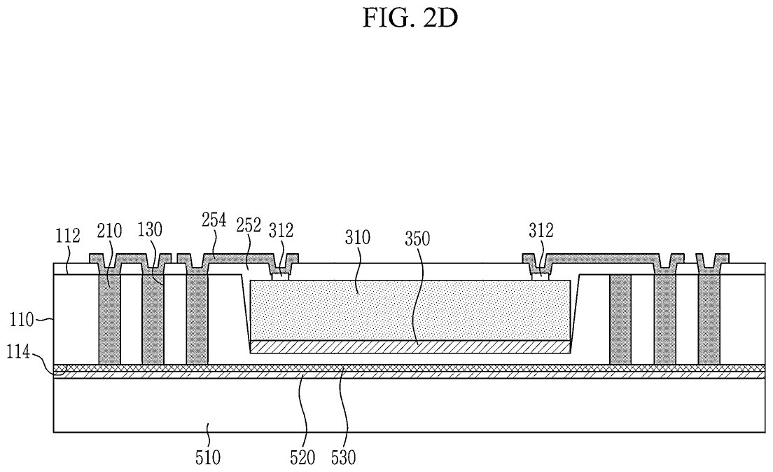

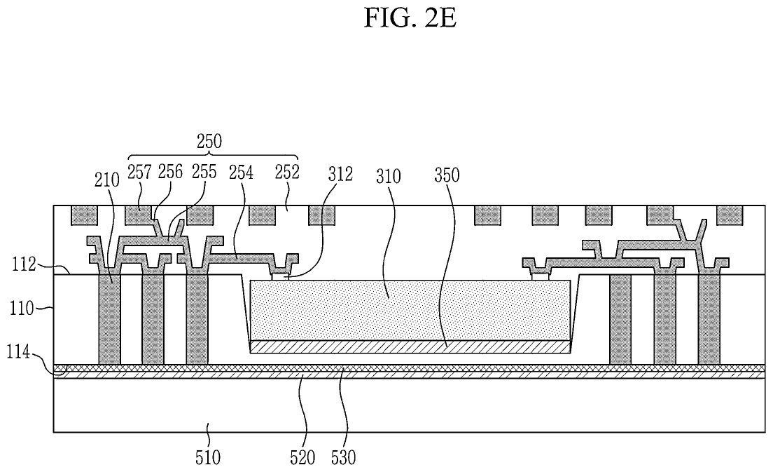

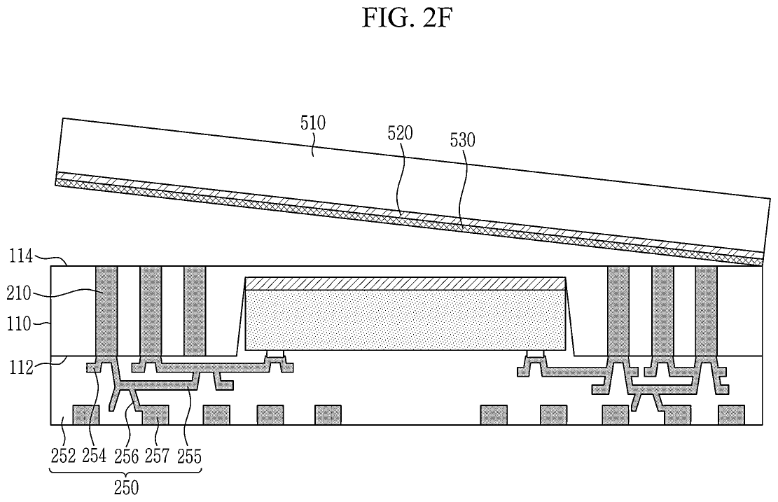

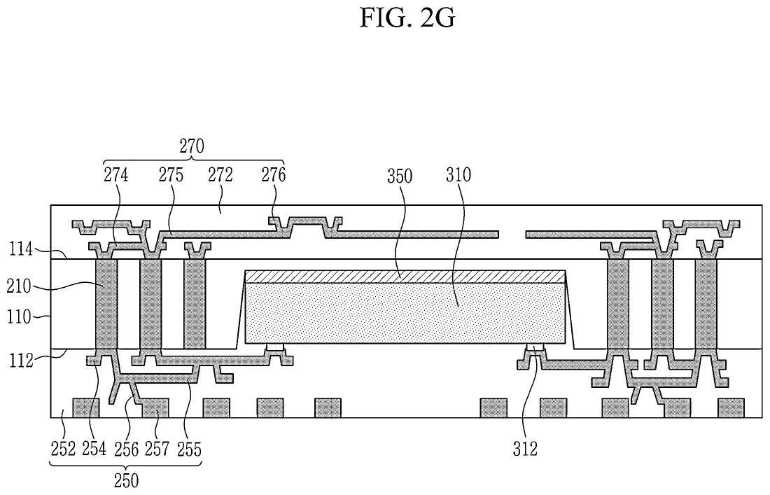

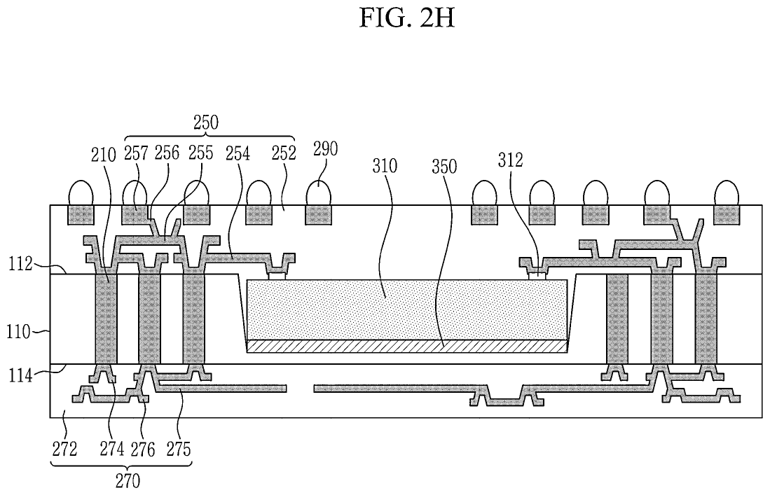

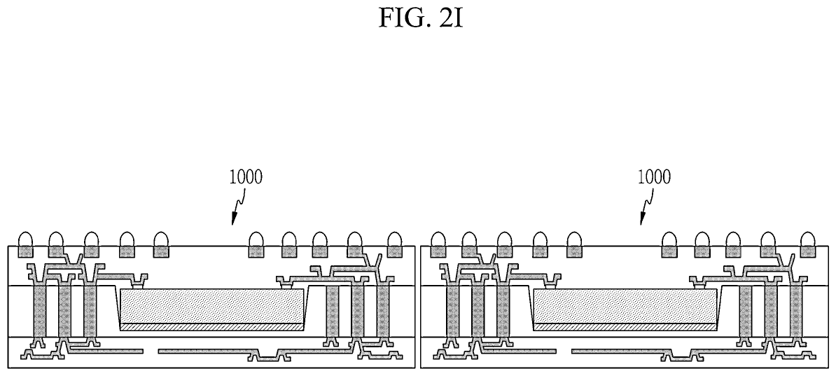

Next, referring to FIG. 2A to FIG. 2I, a semiconductor package and a manufacturing method thereof according to an example embodiment will be described.

FIG. 2A to FIG. 2I sequentially show a manufacturing method of a semiconductor package according to an example embodiment.

An embodiment shown in FIG. 2A to FIG. 2I is almost the same as the embodiment shown in FIG. 1A to FIG. 1I, and thus repeated description thereof will be omitted and the differences will be mainly described. In addition, the same reference numerals are used for the same constituent elements as in the preceding embodiment. The present embodiment differs from the previous embodiment in that it uses a carrier substrate.

As shown in FIG. 2A, a glass substrate 110 is prepared. The glass substrate 110 may include a first side 112 and a second side 114 that face each other. The glass substrate 110 may include a groove 120 and a hole 130, and the hole 130 may be positioned on both sides of the groove 120.

The overall shape of the glass substrate 110 may be similar to that of the previous embodiment. A thickness of the glass substrate 110 may be thinner than in the previous embodiment. In the present embodiment, a process is carried out using a carrier substrate, and thus even though the thickness of the glass substrate 110 is formed thinner, the process can be stably carried out.

As shown in FIG. 2B, a carrier substrate 510 is prepared. For example, the carrier substrate 510 may include a semiconductor material such as glass, plastic, a ceramic material, or silicon. A thickness of carrier substrate 510 may be thicker than that of the glass substrate 110, but is not limited thereto.

Subsequently, a first metal layer 520 and a second metal layer 530 are sequentially formed on the carrier substrate 510. For example, the first metal layer 520 may be made of titanium (Ti), and the second metal layer 530 may be made of copper (Cu). The first metal layer 520 may be made of a material that can improve adherence between the carrier substrate 510 and the second metal layer 530.

Subsequently, the glass substrate 110 is positioned on the second metal layer 530. The second side 114 of the glass substrate 110 may contact the second metal layer 530. In some cases, a separate adhesive member may be used such that the glass substrate 110 may be adhered to the carrier substrate 510.

Subsequently, conductive connection members 210 are formed inside the holes 130 of the glass substrate 110. The conductive connection members 210 may be formed to fill the inside of the holes 130. For example, the conductive connection members 210 may be formed using an electroplating process. An upper surface of the conductive connection members 210 and a first side 112 of the glass substrate 110 may be flat (e.g., coplanar).

As shown in FIG. 2C, the semiconductor chip 310 may be attached to the inside of the groove 120 of the glass substrate 110. The semiconductor chip 310 may be attached to an inner bottom surface of the groove 120 of the glass substrate 110 using the adhesive member 350. The adhesive member 350 is positioned between the glass substrate 110 and the semiconductor chip 310 within the groove 120.

The semiconductor chip 310 may include electrodes 312. The electrodes 312 may be positioned on an upper surface of the semiconductor chip 310 and may be made of a conductive material.

As shown in FIG. 2D, an insulation layer 252 and a first wiring layer 254 are formed on the first side 112 of the glass substrate 110. A space may exist between the groove 120 of the glass substrate 110 and the semiconductor chip 310, and the space may be filled by the insulation layer 252. The first wiring layer 254 may be connected to the conductive connection members 210 and the semiconductor chip 310.

As shown in FIG. 2E, the insulation layer 252, a second wiring layer 255, a third wiring layer 256, and pad portions 257 are formed on the first wiring layer 254. The insulation layer 252, the first wiring layer 254, the second wiring layer 255, the third wiring layer 256, and the pad portions 257 may form a first redistribution structure 250. The first redistribution structure 250 may be positioned on the first side 112 of the glass substrate 110.

As shown in FIG. 2F, the glass substrate 110 is turned over such that the second side 114 is placed on top. Subsequently, the carrier substrate 510 is separated from the glass substrate 110 and removed. In the process of removing the carrier substrate 510, the first metal layer 520 and the second metal layer 530 may also be removed. Accordingly, one end of each of the conductive connection members 210 and the second side 114 of the glass substrate 110 may be exposed to the outside. The one end of each of the conductive connection members 210 exposed to the outside and the second side 114 of the glass substrate 110 may be flat (e.g., coplanar).

As shown in FIG. 2G, a second redistribution structure 270 is formed on the second side 114 of the glass substrate 110. The second redistribution structure 270 may include an insulation layer 272, a first wiring layer 274, a second wiring layer 275, and a third wiring layer 276. The first wiring layer 274 of the second redistribution structure 270 may be connected to the conductive connection members 210.

As shown in FIG. 2H, the glass substrate 110 is turned over again such that the first side 112 is placed on top. Subsequently, connection members 290 are formed on the first redistribution structure 250. The connection members 290 may be connected to the pad portions 257 of the first redistribution structure 250. For example, each of the connection members 290 may be connected to a corresponding one of the pad portions 257.

As shown in FIG. 2I, a plurality of semiconductor packages 1000 may be separated by carrying out a dicing process. The glass substrate 110 may include a plurality of grooves 120 and a plurality of holes 130 positioned around the respective grooves 120. At least one semiconductor chip 310 may be positioned within each groove 120. The plurality of semiconductor packages 1000 may be separated by performing a process of cutting the glass substrate 110.

The semiconductor package 1000 according to the embodiment can be manufactured by the semiconductor package manufacturing method shown in FIG. 2A to FIG. 2I. The semiconductor package 1000 according to the present embodiment may have a similar structure to that of the semiconductor package according to the previous embodiment. For example, although there are some differences between the present embodiment and the preceding embodiment in manufacturing method, the shape of the completed semiconductor package may be similar.

The semiconductor package according to the embodiment may have structural stability and improved reliability in the manufacturing process.

Compared to the previous embodiment, a thickness of the glass substrate may be relatively thin by using the carrier substrate in the present embodiment. Therefore, a groove depth of a glass substrate may be relatively small. The present embodiment may be suitable for manufacturing a thin semiconductor package.

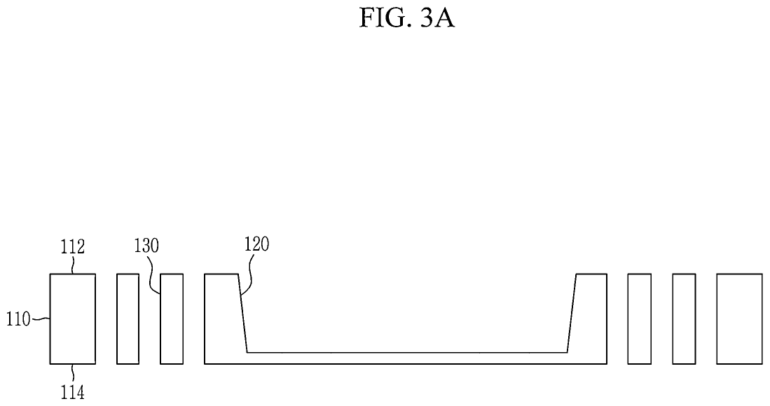

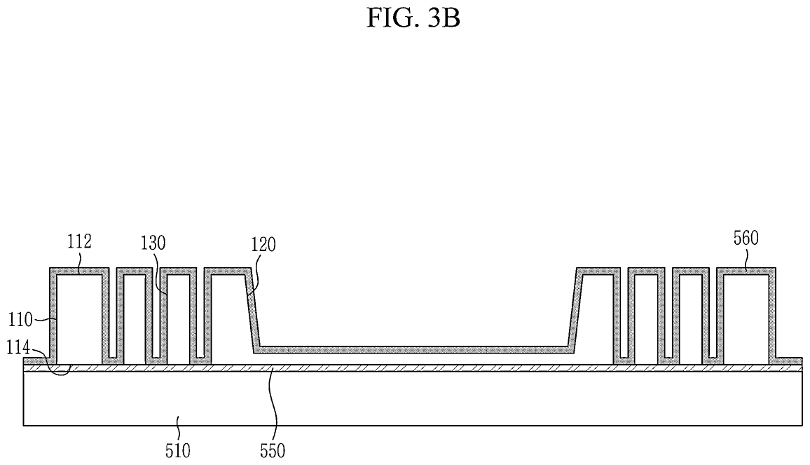

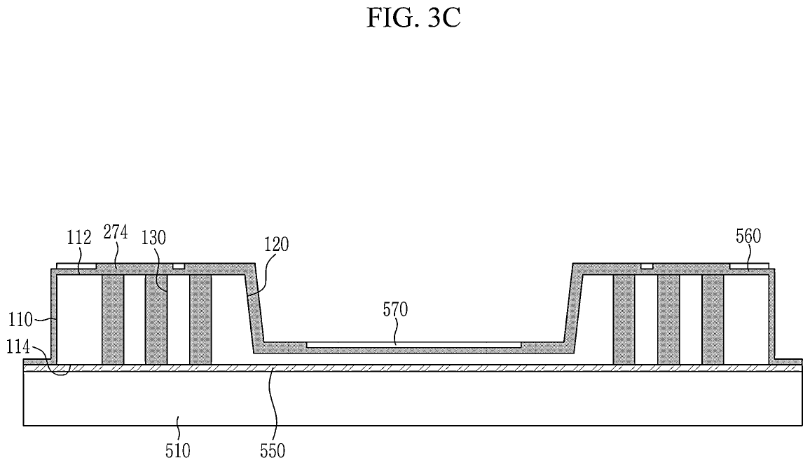

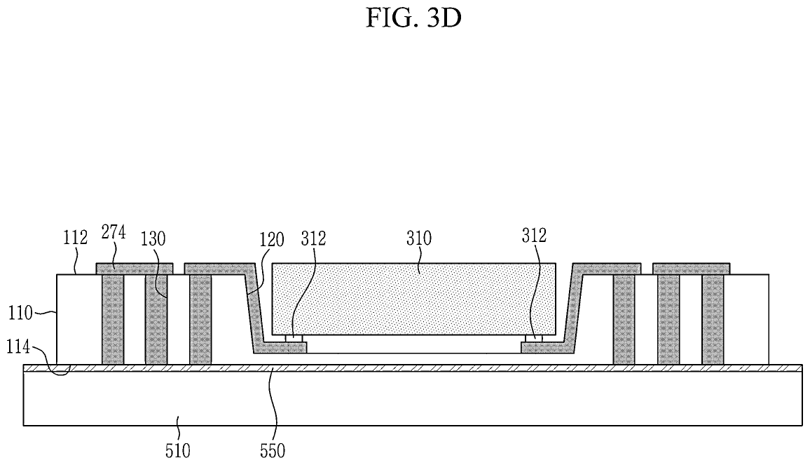

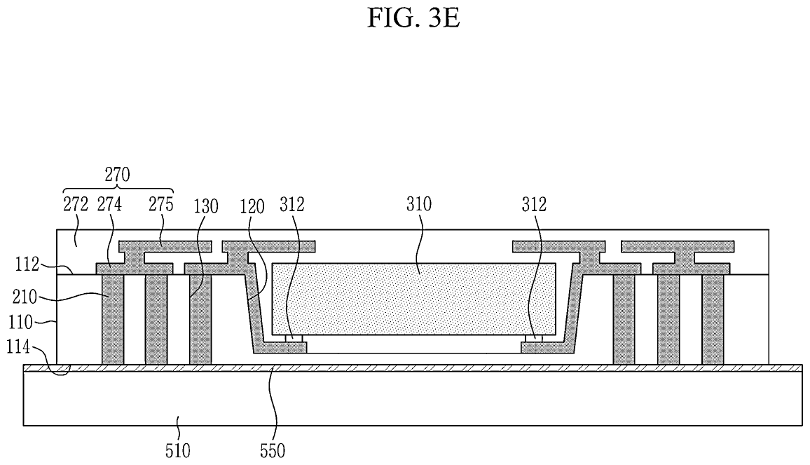

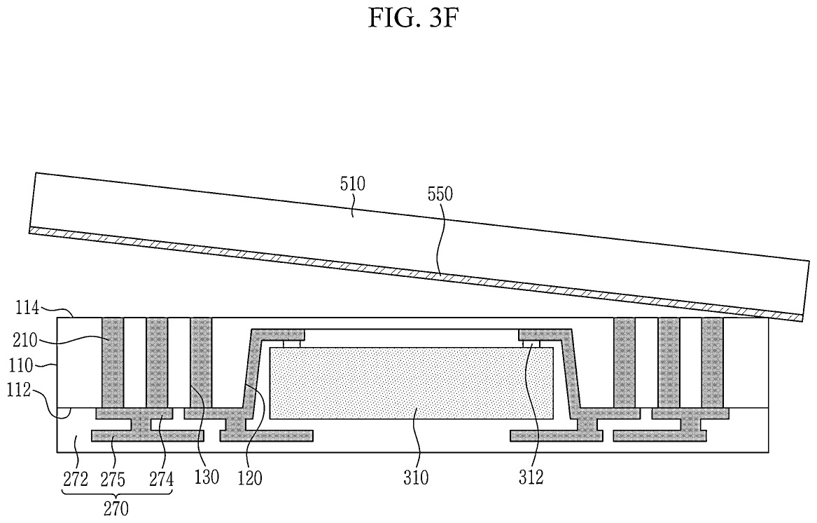

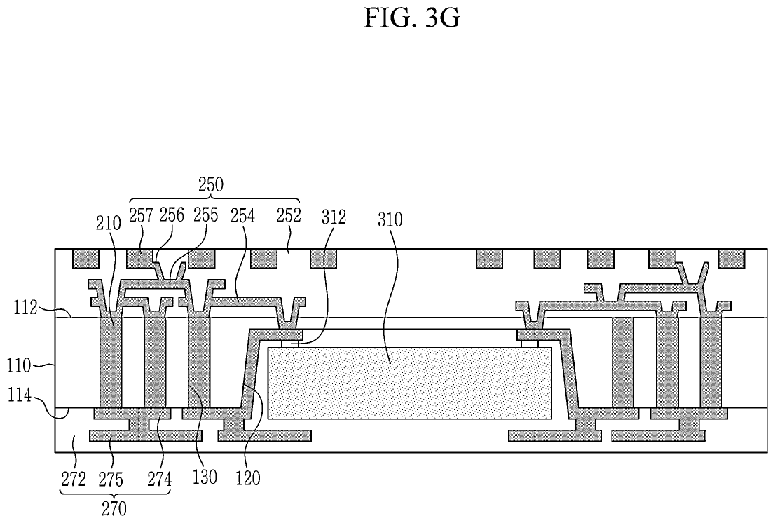

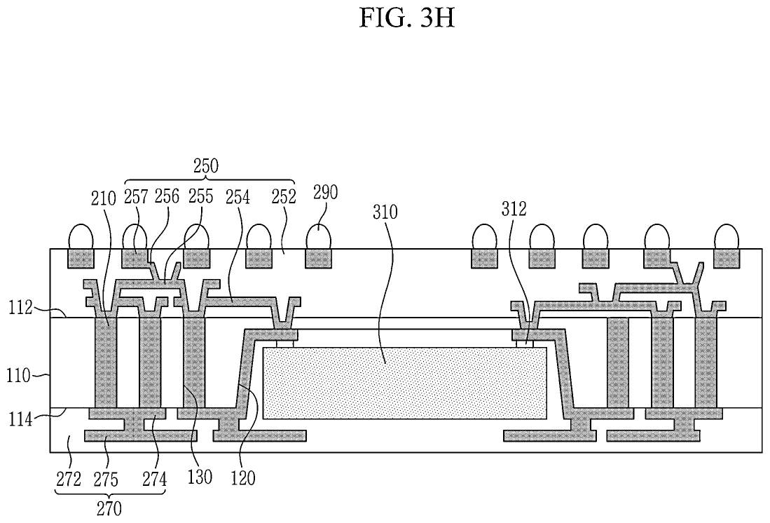

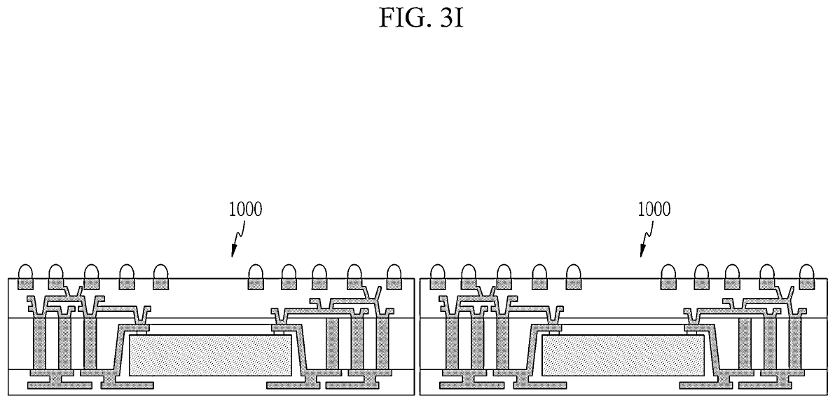

Next, referring to FIG. 3A to FIG. 3I, a semiconductor package and a manufacturing method thereof according to an example embodiment will be described.

FIG. 3A to FIG. 3I sequentially show a semiconductor package and a manufacturing method thereof according to an example embodiment.

An embodiment shown in FIG. 3A to FIG. 3I is almost the same as the embodiment shown in FIG. 1A to FIG. 1I, so repeated description thereof will be omitted and a description will focus on the differences. In addition, the same reference numerals are used for the same constituent elements as in the preceding embodiment. The present embodiment differs from the previous embodiment in that at least a portion of the wiring layer is first formed and then a semiconductor chip is attached.

As shown in FIG. 3A, a glass substrate 110 is prepared. The glass substrate 110 may include a first side 112 and a second side 114 that face each other. The glass substrate 110 may include a groove 120 and holes 130, and the holes 130 may be positioned on both sides of the groove 120.

As shown in FIG. 3B, a carrier substrate 510 is prepared.

Subsequently, the carrier substrate 510 is attached to the glass substrate 110. A carrier substrate 510 may be attached to the second side 114 of the glass substrate 110. The carrier substrate 510 may be attached to the glass substrate 110 by a carrier adhesive member 550. The carrier adhesive member 550 may be positioned between the glass substrate 110 and the carrier substrate 510. For example, the carrier adhesive member 550 may include a thermosetting resin, a thermoplastic resin, or a UV curable resin. The carrier adhesive member 550 may be an adhesive tape containing an acrylic resin or an epoxy resin.

Next, a lower barrier metal layer 560 is formed on the glass substrate 110. The lower barrier metal layer 560 may be formed using a deposition process. A lower barrier metal layer 560 may be formed by depositing a metal material on the glass substrate 110. The lower barrier metal layer 560 may be positioned on the first side 112 of the glass substrate 110 and may be positioned inside the holes 130. The lower barrier metal layer 560 is formed to cover an inner wall of the holes 130, and is not formed to fill the entire inside of the holes 130.

The lower barrier metal layer 560 may include a plurality of metal layers. For example, the lower barrier metal layer 560 may include a layer made of titanium (Ti) and a layer made of copper (Cu).

As shown in FIG. 3C, a photoresist is applied on the glass substrate 110, and the photoresist is patterned using a photo process to form a photoresist pattern 570. The photoresist pattern 570 may be positioned on the lower barrier metal layer 560. The photoresist pattern 570 may be positioned above the first side 112 of the glass substrate 110 and inside the groove 120.

Subsequently, conductive connection members 210 are formed inside the holes 130 of the glass substrate 110, and a first wiring layer 274 connected to the conductive connection members 210 is formed. The conductive connection members 210 and the first wiring layer 274 may be formed using an electroplating process. The conductive connection members 210 and the first wiring layer 274 may be formed in a portion where the photoresist pattern 570 is not positioned. The conductive connection members 210 and the first wiring layer 274 may be formed simultaneously using one process. The conductive connection members 210 and the first wiring layer 274 may be electrically connected to each other and may be integrally formed.

The conductive connection members 210 may be formed to fill the inside of the holes 130. The first wiring layer 274 may be positioned on the conductive connection members 210 and is connected to the conductive connection members 210. The first wiring layer 274 may be positioned on the first side 112 of the glass substrate 110 and may be positioned within the groove 120 of the glass substrate 110. In this case, the first wiring layer 274 may be continuously formed along the sidewall within the groove 120 of the glass substrate 110 and may extend to the bottom surface.

Subsequently, the photoresist pattern 570 and lower barrier metal layer 560 are removed.

As shown in FIG. 3D, the semiconductor chip 310 may be attached to the inside of the groove 120 of the glass substrate 110.

The semiconductor chip 310 may include electrodes 312. The electrodes 312 may be positioned on one surface of the semiconductor chip 310 and may be made of a conductive material. The surface of the semiconductor chip 310 on which the electrodes 312 are formed faces a bottom surface of the groove 120 of the glass substrate 110. Subsequently, the semiconductor chip 310 is moved into the groove 120 of the glass substrate 110, and the electrodes 312 of the semiconductor chip 310 are in contact with the first wiring layer 274. The electrodes 312 of the semiconductor chip 310 may be connected to the first wiring layer 274.

As shown in FIG. 3E, an insulation layer 272 and a second wiring layer 275 are formed on the first wiring layer 274. The insulation layer 272, the first wiring layer 274, and the second wiring layer 275 may form a second redistribution structure 270.

In the previous embodiment, the second redistribution structure 270 may be positioned on the second side 114 of the glass substrate 110, and in the present embodiment, the second redistribution structure 270 may be positioned on the first side 112 of the glass substrate 110.

In the previous embodiment, the first redistribution structure 250 may be connected to the semiconductor chip 310, and in the present embodiment, the second redistribution structure 270 may be connected to the semiconductor chip 310.

A space may exist between the groove 120 of the glass substrate 110 and the semiconductor chip 310, and the space may be filled by the insulation layer 272.

As shown in FIG. 3F, the glass substrate 110 is turned over such that the second side 114 is placed on top. Subsequently, the carrier substrate 510 is separated from the glass substrate 110 and removed. In the process of removing the carrier substrate 510, the carrier adhesive member 550 may also be removed. Accordingly, one end of each of the conductive connection members 210 and the second side 114 of the glass substrate 110 may be exposed to the outside. The one end of each of the conductive connection members 210 exposed to the outside and the second side 114 of the glass substrate 110 may be flat (e.g., coplanar).

As shown in FIG. 3G, a first redistribution structure 250 is formed on the second side 114 of the glass substrate 110. The first redistribution structure 250 may include an insulation layer 252, a first wiring layer 254, a second wiring layer 255, a third wiring layer 256, and pad portions 257. The first wiring layer 254 of the first redistribution structure 250 may be connected to the conductive connection members 210.

As shown in FIG. 3H, connection members 290 are formed on the first redistribution structure 250. The connection members 290 may be connected to the pad portions 257 of the first redistribution structure 250. For example, each of the connections members 290 may be connected to a corresponding one of the pad portions 257.

As shown in FIG. 3I, a plurality of semiconductor packages 1000 may be separated by carrying out a dicing process. The glass substrate 110 may include a plurality of grooves 120 and a plurality of holes 130 positioned around the respective grooves 120. At least one semiconductor chip 310 may be positioned within each groove 120. The plurality of semiconductor packages 1000 may be separated by performing a process of cutting the glass substrate 110.

The semiconductor package 1000 according to the embodiment can be manufactured by the semiconductor package manufacturing method shown in FIG. 3A to FIG. 3I. The semiconductor package 1000 according to the present embodiment may have a similar structure to that of the semiconductor package according to the previous embodiment. However, there may be some structural differences. In the previous embodiment, the first redistribution structure 250 may be positioned on the first side 112 of the glass substrate 110, and the second redistribution structure 270 may be positioned on the second side 114. In the present embodiment, the second redistribution structure 270 may be positioned on the first side 112 of the glass substrate 110, and the first redistribution structure may be positioned on the second side 114. In the previous embodiment, the second redistribution structure does not extend to the bottom surface inside the groove of the glass substrate, but in the present embodiment, the second redistribution structure 270 extends to the bottom surface inside the groove 120 of the glass substrate 110. In addition, a second redistribution structure 270 may be connected to the semiconductor chip 310 inside the groove 120.

The semiconductor package according to the embodiment may have structural stability and improved reliability in the manufacturing process.

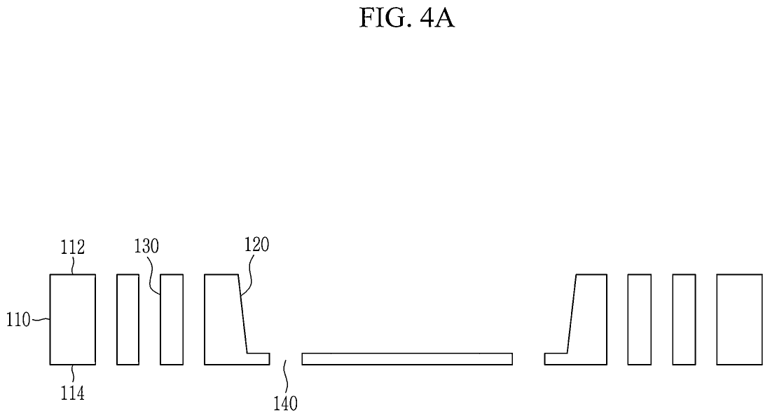

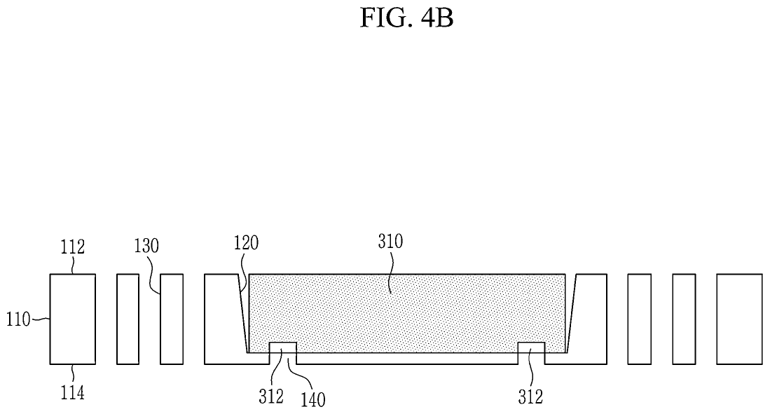

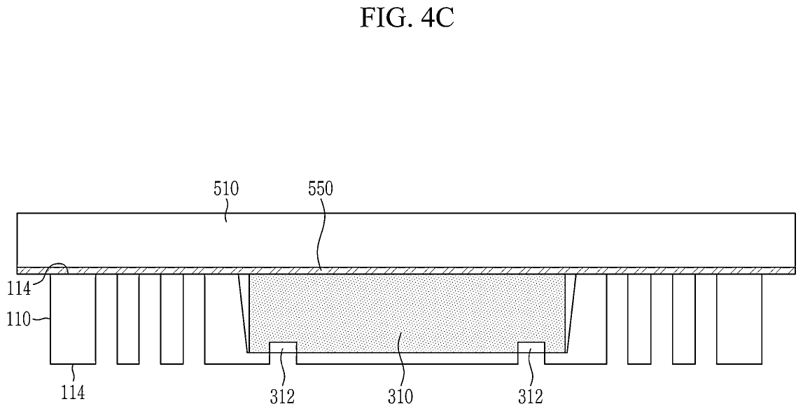

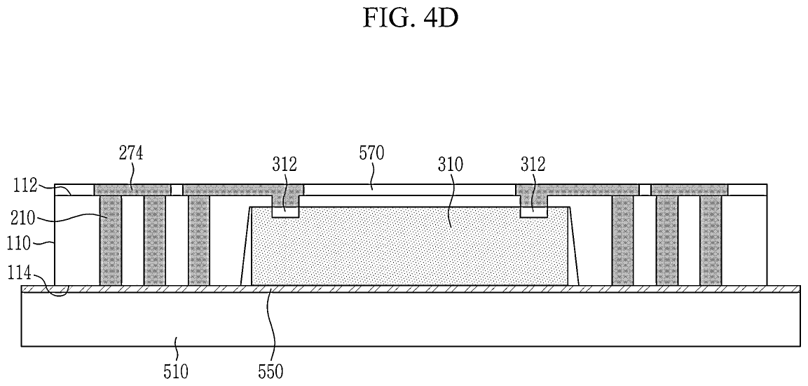

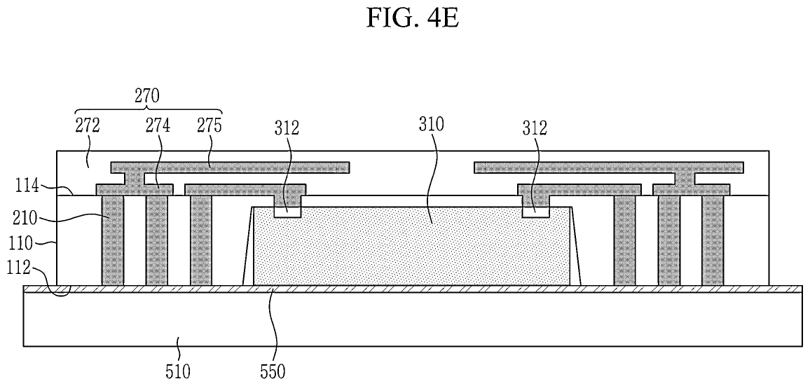

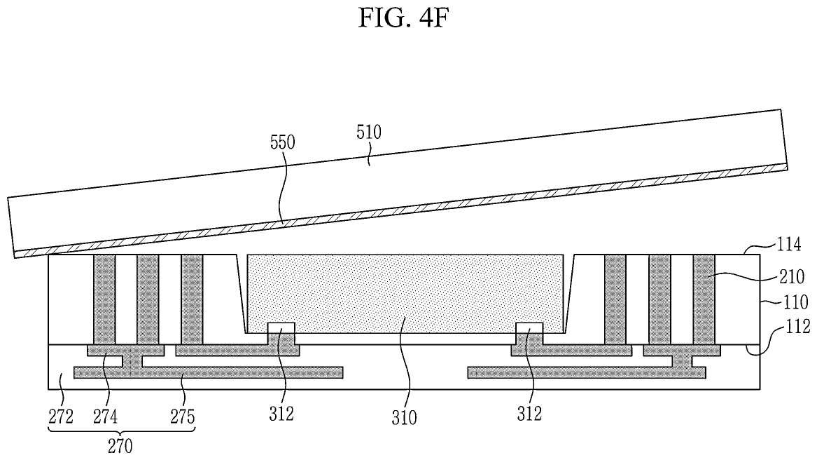

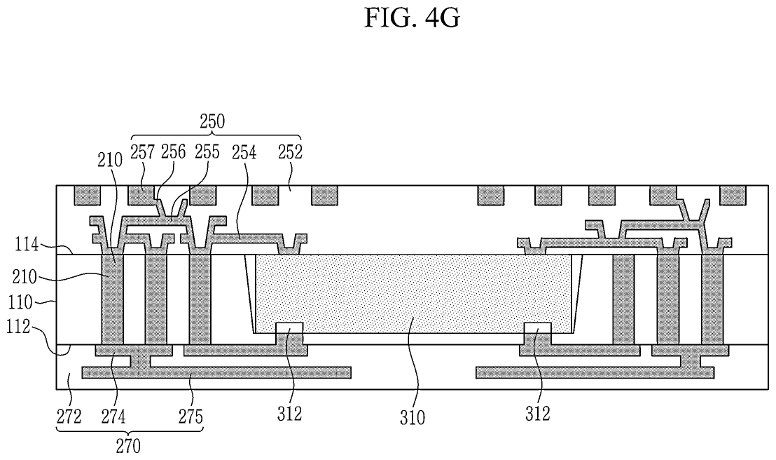

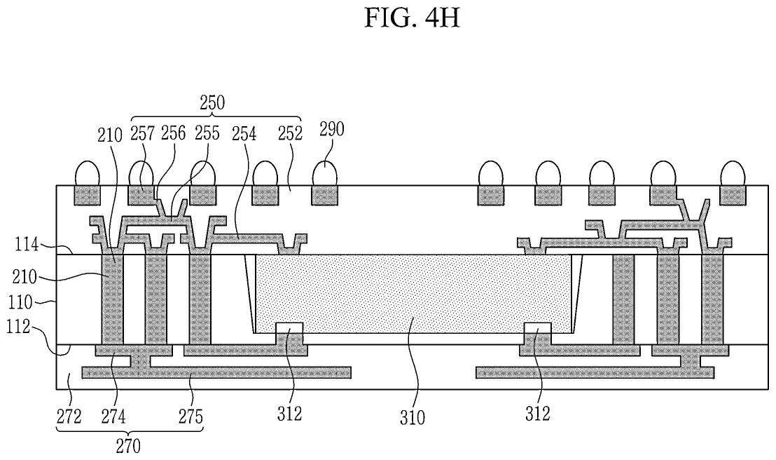

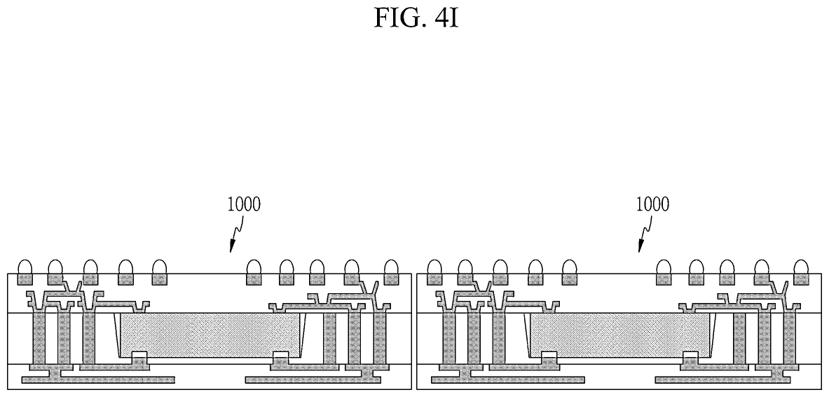

Next, referring to FIG. 4A to FIG. 4I, a semiconductor package and a manufacturing method thereof according to an embodiment will be described.

FIG. 4A to FIG. 4I sequentially show a semiconductor package and a manufacturing method thereof according to an embodiment.

An embodiment shown in FIG. 4A to FIG. 4I is almost the same as the embodiment shown in FIG. 1A to FIG. 1I, and a description thereof will be omitted and a description will focus on the differences. In addition, the same reference numerals are used for the same constituent elements as in the preceding embodiment. The present embodiment is different from the previous embodiment in that an auxiliary hole is further formed under a groove of a glass substrate.

As shown in FIG. 4A, a glass substrate 110 is prepared. The glass substrate 110 may include a first side 112 and a second side 114 that face each other. The glass substrate 110 may include a groove 120 and holes 130, and the holes 130 may be positioned on both sides of the groove 120.

The glass substrate 110 may further include auxiliary holes 140. The auxiliary holes 140 may be positioned below the groove 120. The auxiliary holes 140 may pass through a bottom surface of the groove 120. A depth of the auxiliary holes 140 may correspond to a thickness of a portion of the glass substrate 110 positioned under the groove 120. The auxiliary holes 140 may be positioned adjacent to both edges inside the groove 120.

As shown in FIG. 4B, the semiconductor chip 310 may be attached to the inside of the groove 120 of the glass substrate 110. Although not shown, the semiconductor chip 310 may be attached to an inner bottom surface of the groove 120 of the glass substrate 110 by using an adhesive member. In this case, the adhesive member may be positioned between the glass substrate 110 and the semiconductor chip 310 within the groove 120.

The semiconductor chip 310 may include electrodes 312. The electrodes 312 may be positioned on one surface of the semiconductor chip 310 and may be made of a conductive material. A surface of the semiconductor chip 310 on which the electrodes 312 are formed faces the bottom surface of the groove 120 of the glass substrate 110. Subsequently, the semiconductor chip 310 is moved into the groove 120 of the glass substrate 110, and the electrodes 312 of the semiconductor chip 310 are positioned directly above the auxiliary holes 140. Accordingly, the electrodes 312 of the semiconductor chip 310 may be externally exposed through the auxiliary holes 140.

As shown in FIG. 4C, a carrier substrate 510 is prepared.

Subsequently, the carrier substrate 510 is attached to the glass substrate 110. The carrier substrate 510 may be attached to the first side 112 of the glass substrate 110. The carrier substrate 510 may be attached to the glass substrate 110 by a carrier adhesive member 550. The carrier adhesive member 550 may be positioned between the glass substrate 110 and the carrier substrate 510. The carrier adhesive member 550 may also be positioned between the semiconductor chip 310 and the carrier substrate 510. Accordingly, the carrier substrate 510 may be attached to the semiconductor chip 310 by the carrier adhesive member 550.

As shown in FIG. 4D, the glass substrate 110 is turned over such that the second side 114 is placed on top. A photoresist is applied on the glass substrate 110, and the photoresist is patterned using a photo process to form a photoresist pattern 570. The photoresist pattern 570 may be positioned on the second side 114 of the glass substrate 110.

Subsequently, conductive connection members 210 are formed inside the holes 130 of the glass substrate 110, and a first wiring layer 274 connected to the conductive connection members 210 is formed. The conductive connection members 210 and the first wiring layer 274 may be formed using an electroplating process. The conductive connection members 210 and the first wiring layer 274 may be formed in a portion where the photoresist pattern 570 is not positioned. The conductive connection members 210 and the first wiring layer 274 may be formed simultaneously using one process. The conductive connection members 210 and the first wiring layer 274 may be electrically connected to each other and may be integrally formed.

The conductive connection members 210 may be formed to fill the inside of the holes 130. The first wiring layer 274 may be positioned on the conductive connection members 210 and may be connected to the conductive connection members 210. The first wiring layer 274 may be positioned on the second side 114 of the glass substrate 110, and may be formed to fill the inside of the auxiliary holes 140 of the glass substrate 110. The first wiring layer 274 may be connected to the electrodes 312 of the semiconductor chip 310 through the auxiliary holes 140.

Next, the photoresist pattern 570 is removed.

As shown in FIG. 4E, an insulation layer 272 and a second wiring layer 275 are formed on the first wiring layer 274. The insulation layer 272, the first wiring layer 274, and the second wiring layer 275 may form a second redistribution structure 270.

In the previous embodiment, the first redistribution structure 250 may be connected to the semiconductor chip 310, and in the present embodiment, the second redistribution structure 270 may be connected to the semiconductor chip 310 through the auxiliary holes 140 formed in the groove 120 of the glass substrate 110.

As shown in FIG. 4F, the glass substrate 110 is turned over such that the first side 112 is placed on top. Subsequently, the carrier substrate 510 is removed from the glass substrate 110. In a process of removing the carrier substrate 510, the carrier adhesive member 550 may also be removed. Accordingly, one end of each of the conductive connection members 210 and the second side 114 of the glass substrate 110 may be exposed to the outside. The one end of each of the conductive connection members 210 exposed to the outside and the second side 114 of the glass substrate 110 may be flat (e.g., coplanar).

As shown in FIG. 4G, the first redistribution structure 250 is formed on the first side 112 of the glass substrate 110. The first redistribution structure 250 may include an insulation layer 252, a first wiring layer 254, a second wiring layer 255, a third wiring layer 256, and pad portions 257. The first wiring layer 254 of the first redistribution structure 250 may be connected to the conductive connection members 210.

A space may exist between the groove 120 of the glass substrate 110 and the semiconductor chip 310, and the space may be filled by the insulation layer 252.

As shown in FIG. 4H, connection members 290 are formed on the first redistribution structure 250. The connection members 290 may be connected to the pad portions 257 of the first redistribution structure 250. For example, each of the connection members 290 may be connected to a corresponding one of the pad portions 257.

As shown in FIG. 4I, a plurality of semiconductor packages 1000 may be separated by carrying out a dicing process. The glass substrate 110 may include a plurality of grooves 120 and a plurality of holes 130 positioned around the respective grooves 120. At least one semiconductor chip 310 may be positioned within each groove 120. The plurality of semiconductor packages 1000 may be separated by performing a process of cutting the glass substrate 110.

The semiconductor package 1000 according to the embodiment may be manufactured by the semiconductor package manufacturing method shown in FIG. 4A to FIG. 4I. The semiconductor package 1000 according to the present embodiment may have a similar structure to that of the semiconductor package according to the previous embodiment. However, there may be some structural differences. In the previous embodiment, no auxiliary hole is formed under the groove of the glass substrate, and in the present embodiment, the auxiliary holes 140 are formed under the groove 120 of the glass substrate 110. In addition, the second redistribution structure 270 and the semiconductor chip 310 may be connected through the auxiliary holes 140.

The semiconductor package according to the embodiment may have structural stability and improved reliability in the manufacturing process.

While this disclosure has been described in connection with what is presently considered to be practical embodiments, it is to be understood that the invention is not limited to the disclosed embodiments. On the contrary, it is intended to cover various modifications and equivalent arrangements included within the spirit and scope of the appended claims.

What is claimed is:

1. A manufacturing method of a semiconductor package, comprising:
preparing a glass substrate that includes a groove and a hole positioned at a side of the groove;
forming a conductive connection member to fill inside the hole of the glass substrate;
attaching a semiconductor chip inside the groove of the glass substrate;
forming a first redistribution structure for connection with the semiconductor chip and the conductive connection member on a first side of the glass substrate; and
forming a second redistribution structure for connection with the conductive connection member on a second side of the glass substrate.

2. The manufacturing method of the semiconductor package of claim 1,
wherein a plurality of holes are positioned on both sides of the groove, respectively,
wherein a depth of each of the plurality of holes is about 300 μm or more and about 500 μm or less, and
wherein a width of each of the plurality of holes is about 20 μm or more and about 200 μm or less.

3. The manufacturing method of the semiconductor package of claim 1, wherein a thickness of a portion of the glass substrate positioned below the groove is about 50 μm or more and about 100 μm or less.

4. The manufacturing method of the semiconductor package of claim 1, wherein an angle of inclination between a bottom surface and a side surface of the glass substrate inside the groove is about 90 degrees or more and about 95 degrees or less.

5. The manufacturing method of the semiconductor package of claim 1, wherein in the forming of the conductive connection member, the conductive connection member is formed by filling a conductive material in the form of paste inside the hole.

6. The manufacturing method of the semiconductor package of claim 5, wherein in the forming of the conductive connection member, a first side of the conductive connection member is coplanar with a first side of the glass substrate, and a side end of the conductive connection member is coplanar with a second side of the glass substrate.

7. The manufacturing method of the semiconductor package of claim 1,
wherein the semiconductor chip is attached to a bottom surface of the glass substrate inside the groove, and
wherein an adhesive member is positioned between the semiconductor chip and the glass substrate.

8. The manufacturing method of the semiconductor package of claim 1,
wherein the semiconductor chip comprises an electrode, and
wherein the first redistribution structure is connected to the electrode of the semiconductor chip.

9. The manufacturing method of the semiconductor package of claim 8, wherein the first redistribution structure comprises:
at least one wiring layer connected to the conductive connection member and the semiconductor chip;
a pad portion connected to the at least one wiring layer; and
an insulation layer positioned between the at least one wiring layer and the glass substrate, between wiring layers of the plurality of wiring layers, and between the at least one wiring layer and the pad portion.

10. The manufacturing method of the semiconductor package of claim 9, wherein the second redistribution structure comprises:
at least one wiring layer connected to the conductive connection member; and
an insulation layer positioned between the at least one wiring layer and the glass substrate and between the wiring layers of the at least one wiring layer.

11. The manufacturing method of the semiconductor package of claim 9, further comprising:
forming a connection member connected with the pad portion on the first redistribution structure.

12. The manufacturing method of the semiconductor package of claim 1,
wherein the glass substrate comprises a plurality of grooves, and a plurality of holes positioned around the respective grooves, and
wherein a semiconductor chip is attached to the inside of each of the plurality of grooves.

13. The manufacturing method of the semiconductor package of claim 12, further comprising:
separating the glass substrate into a plurality of semiconductor packages through a cutting process.

14. The manufacturing method of the semiconductor package of claim 1, further comprising:
attaching a carrier substrate to the glass substrate; and
separating the carrier substrate from the glass substrate after forming the first redistribution structure,
wherein the second redistribution structure is formed after separating the carrier substrate from the glass substrate.

15. A manufacturing method of a semiconductor package, comprising:
preparing a glass substrate that includes a groove and a hole positioned at a side of the groove;
attaching a carrier substrate to the glass substrate;
forming a conductive connection member to fill the inside of the hole of the glass substrate using an electroplating process;
attaching a semiconductor chip to the inside of the groove of the glass substrate;
forming a first redistribution structure for connection with the semiconductor chip and the conductive connection member on a first side of the glass substrate;
separating the carrier substrate from the glass substrate; and
forming a second redistribution structure for connected with the conductive connection member on a second side of the glass substrate.

16. The manufacturing method of the semiconductor package of claim 15, further comprising:
forming a photoresist pattern on the first side of the glass substrate,
wherein the first redistribution structure is formed in a portion where the photoresist pattern is not formed using an electroplating process.

17. The manufacturing method of the semiconductor package of claim 15,
wherein the forming the conductive connection member and the forming at least a part of the first redistribution structure are carried out in a single process, and
wherein the semiconductor chip is attached after forming the at least the part of the first redistribution structure.

18. The manufacturing method of the semiconductor package of claim 17,
wherein the first redistribution structure is formed to extend to the inside of the groove, and
wherein the semiconductor chip is positioned on the first redistribution structure inside the groove.

19. The manufacturing method of the semiconductor package of claim 15,
wherein the glass substrate further comprises an auxiliary hole positioned below the groove, and
wherein the semiconductor chip and the first redistribution structure are connected through the auxiliary hole.

20. A semiconductor package comprising:
a glass substrate that includes a groove and a plurality of holes positioned around the groove;
a semiconductor chip positioned inside the groove of the glass substrate and attached to the glass substrate;
a plurality of conductive connection members positioned inside the plurality of holes of the glass substrate;
a first redistribution structure positioned on a first side of the glass substrate and connected to the semiconductor chip and the plurality of conductive connection members;
a connection member positioned on the first redistribution structure; and
a second redistribution structure positioned on a second side of the glass substrate and connected to the plurality of conductive connection members.
